(19) United States
(12) Patent Application Publication
(10) Pub. No.: US 2016/0343739 A1
(43) Pub. Date: Nov. 24, 2016

(54) THIN FILM TRANSISTOR, METHOD OF MANUFACTURING THIN FILM TRANSISTOR, ARRAY SUBSTRATE AND DISPLAY DEVICE

(71) Applicant: BOE TECHNOLOGY GROUP CO., LTD., Beijing (CN)

(72) Inventor: Xiang Liu, Beijing (CN)

(21) Appl. No.: 15/094,553

(22) Filed: Apr. 8, 2016

(30) Foreign Application Priority Data
May 18, 2015 (CN) 201510254665.X

(51) Int. Cl. H01L 27/12; H01L 33/42; H01L 29/66; H01L 29/45; H01L 29/786

(52) U.S. Cl. CPC H01L 27/1225; H01L 29/458; H01L 29/7869; H01L 29/66969; H01L 27/124; H01L 33/42

(57) ABSTRACT

Embodiments of the present invention disclose a thin film transistor, a method of manufacturing a thin film transistor, an array substrate and a display device, which may ensure electrical connection between source and drain electrodes and an active layer without configuring any through hole due to providing an etch stop layer between the active layer and the source and drain electrodes, a portion of the etch stop layer being in contact with the source and drain electrode is made of metal or metal alloy; and may ensure insulation between the source and the drain electrodes when the thin film transistor is turned-off, ensuring normal operation of the thin film transistor, by oxidating the portion of the etch stop layer at the position between the source and the drain electrodes as an insulating material. The etch stop layer may not only prevent the active layer from being damaged when etching the source and drain electrodes, but also prevent the active layer from other adverse effects from subsequent processes, such as adverse effects from water, hydrogen and oxygen, etc., thereby enhancing performance of the thin film transistor, just because of providing the etch stop layer between the active layer and the source and drain electrodes in the thin film transistor.

### CROSS-REFERENCE TO RELATED APPLICATIONS

This application claims priority of Chinese Application No. 201510254665.X, filed May 18, 2015, entitled “Thin film transistor, method of manufacturing a thin film transistor, array substrate and display device”, which is incorporated herein by reference in their entirety.

### BACKGROUND

1. Technical Field

The present invention relates to field of semiconductor technology, and particularly to a thin film transistor, a method of manufacturing a thin film transistor, an array substrate and a display device.

2. Description of the Related Art

As application of a flat panel display is developing, requirements on a display panel become higher. Particularly, mobility of a thin film transistor in the display panel is needed to be in higher level. Recently, an existing thin film transistor is often an amorphous silicon thin film transistor, i.e., an active layer of the thin film transistor is made of amorphous silicon material. However, an amorphous silicon thin film transistor has a rather low mobility of carriers, such as 0.1˜1 cm²V⁻¹ s⁻¹ of mobility of electron, and thus is not adapted to the current development of the display application. A low temperature poly-silicon thin film transistor (LTPS) and an oxide thin film transistor are then approached.

The LTPS has an active layer made of low temperature poly-silicon, which is directed to an poly-silicon transformed from an amorphous silicon at low temperature, and thus has a high mobility of carriers of about 100˜500 cm²V⁻¹ s⁻¹. However, there is still a difficulty in achieving uniformity in this type of thin film transistor. Thus, when used in a large-size panel, it will be subjected to great impediment. The oxide thin film transistor has an active layer made of oxide semiconductor material and may achieve a mobility of carriers of 10 cm²V⁻¹s⁻¹ while ensuring a pretty uniformity in large scale. Thus, the oxide thin film transistor may meet requirements of a large-scale display panel in a better way due to its high mobility, good uniformity, transparence and simple manufacturing process, and thus is received much attention.

Currently, during manufacturing an oxide thin film transistor, a source-drain electrode layer is formed after having formed an oxide active layer. However, when etching the source-drain electrode layer, the oxide active layer may be damaged, which cannot be avoided even adjustment had been made on the etchant. In this instance, the thin film transistor may be degraded in performance, even be damaged to have no properties of switch.

### SUMMARY

Therefore, embodiments of the present invention provide a thin film transistor, a method of manufacturing a thin film transistor, an array substrate and a display device, for avoiding damage on the active layer when etching a source-drain electrode layer.

Thus, an embodiment of the present invention provides a thin film transistor, comprising a base substrate, and a gate electrode, a gate insulating layer, an active layer and a source-drain electrode layer, which are in turn located on the base substrate, wherein, the thin film transistor further comprises:

an etch stop layer located between the active layer and the source-drain electrode layer, orthogonal projection of the etch stop layer on the base substrate being of superposition with that of the active layer on the base substrate, a portion of the etch stop layer under the source-drain electrode layer being made of metal or metal alloy, and a portion of the etch stop layer at a position corresponding to a region between a source electrode and a drain electrode in the source-drain electrode layer being made of oxide of the metal or metal alloy, which is an insulating material.

Preferably, in the thin film transistor according to the embodiment of the present invention, the source-drain electrode layer is made of copper and the etch stop layer is made of a material that is different from that of the source-drain electrode layer.

Preferably, the thin film transistor according to the embodiment of the present invention further comprising:

an oxidation resistant layer located on the source-drain electrode layer, wherein orthogonal projection of the oxidation resistant layer on the base substrate is of superposition with that of the source-drain electrode layer on the base substrate.

Preferably, in the thin film transistor according to the embodiment of the present invention, the oxidation resistant layer is made of a metal material, which is different from the material of the source-drain electrode layer.

Preferably, in the thin film transistor according to the embodiment of the present invention, the etch stop layer is made of any of molybdenum, titanium, tungsten, molybdenum alloy, and titanium alloy.

Preferably, in the thin film transistor according to the embodiment of the present invention, the etch stop layer has a thickness in a range of 20 Å˜200 Å.

Preferably, in the thin film transistor according to the embodiment of the present invention, the oxidation resistant layer is made of any of molybdenum, titanium, tungsten, molybdenum alloy, and titanium alloy.

Preferably, in the thin film transistor according to the embodiment of the present invention, the active layer is made of metal oxide.

Preferably, the thin film transistor according to the embodiment of the present invention further comprises a protective layer configured to cover the oxidation resistant layer, the etch stop layer and the gate insulating layer.

Accordingly, an embodiment of the present invention provides a method of manufacturing a thin film transistor, comprising steps of:

forming a gate electrode on a base substrate;

forming a gate insulating layer covering the gate electrode;

forming an active layer and an etch stop layer on the gate insulating layer, wherein the etch stop layer is located on the active layer such that orthogonal projection of the etch stop layer on the base substrate is of superposition with that of the active layer on the base substrate, the etch stop layer being made of metal or metal alloy;

forming a source-drain electrode layer on the etch stop layer;

oxidating a portion of the etch stop layer at a position corresponding a region between a source electrode of the source-drain electrode layer and a drain electrode of the source-drain electrode layer, which is made of metal or metal alloy, to as oxide of the metal or metal alloy, which is an insulating material.

Preferably, in the method of manufacturing the thin film transistor according to the embodiment of the present invention, the step of forming an active layer and an etch stop layer on the gate insulating layer includes:

forming an active layer film on the gate insulating layer;

forming an etch stop layer film on the active layer; and

patterning the active layer film and the etch stop layer film by a single patterning process, so as to form the active layer and the etch stop layer on the gate insulating layer.

Preferably, in the method of manufacturing the thin film transistor according to the embodiment of the present invention, the source-drain electrode is made of copper, which may render reduced resistance; and

the etch stop layer is made of material that is different from the material for the source-drain electrode layer.

Preferably, after forming the source-drain electrode layer on the etch stop layer, the method further includes:

forming an oxidation resistant layer on the source-drain electrode layer, such that orthogonal projection of the oxidation resistant layer on the base substrate is of superposition with that of the source-drain electrode layer on the base substrate.

Preferably, in the method of manufacturing the thin film transistor according to the embodiment of the present invention, the step of forming the source-drain electrode layer and the oxidation resistant layer includes:

forming a source-drain electrode layer film on the etch stop layer;

forming an oxidation resistant layer film on the source-drain electrode layer film; and

patterning the source-drain electrode layer film and the oxidation resistant layer film through a single patterning process to form the source-drain electrode layer and the oxidation resistant layer.

Accordingly, an embodiment of the present invention provides an array substrate comprising the thin film transistor according to the above embodiments of the present invention.

Preferably, the array substrate according to the embodiment of the present invention further includes a transparent electrode on the protective layer, in which the transparent electrode is electrically connected to the drain electrode of the source-drain electrode layer via a through hole that penetrates through the protective layer.

Preferably, in the array substrate according to the embodiment of the present invention, the transparent electrode is made of Indium-tin oxide (ITO) or indium-zinc oxide (IZO), or other transparent metal oxide, with a thickness in a range of 300 Å˜1500 Å.

Accordingly, an embodiment of the present invention provides a display device comprising the array substrate according to the above embodiments of the present invention.

The thin film transistor, the method of manufacturing a thin film transistor, the array substrate and the display device ensure electrical connection between the source and drain electrodes and the active layer without configuring any through hole due to providing the etch stop layer between the active layer and the source and drain electrodes, a portion of which being in contact with the source and drain electrodes is made of metal or metal alloy; and may ensure insulation between the source electrode and the drain electrode when the thin film transistor is turned-off, ensuring normal operation of the thin film transistor, by oxidating the portion of the etch stop layer at the position between the source electrode and the drain electrode as insulating material through the oxidation process. In the above thin film transistor, the etch stop layer may not only prevent the active layer from being damaged when etching the source-drain electrode layer, but also prevent the active layer from other adverse effects from subsequent processes, such as adverse effects from water, hydrogen and oxygen, etc., thereby enhancing performance of the thin film transistor, just because of providing the etch stop layer between the active layer and the source-drain electrode layer in the thin film transistor. The provision of the etch barrier layer may improve performance of the thin film transistor.

### BRIEF DESCRIPTION OF THE DRAWINGS

FIG. 1 is a first schematic structural view of a thin film transistor according to an embodiment of the present invention;

FIG. 2 is a second schematic structural view of a thin film transistor according to an embodiment of the present invention;

FIG. 3 is a third schematic structural view of a thin film transistor according to an embodiment of the present invention;

FIG. 4 is a structural view of an array substrate according to an embodiment of the present invention;

FIG. 5 is a flow chart of a method of manufacturing a thin film transistor according to an embodiment of the present invention; and

FIG. 6a-6i are respectively structural views of the device obtained after performing respective steps of the method according to an embodiment of the present invention.

### DETAILED DESCRIPTION OF EMBODIMENTS

Embodiments of a thin film transistor, a method of manufacturing the thin film transistor, an array substrate and a display device according to embodiments of the present are described below in detail in combination with drawings.

In the drawings, thickness and shape of various films or layers do not reflect actual scale of the thin film transistor and the array substrate, but are intended to illustrate the scheme of the present disclosure.

Embodiments of the present invention provide a thin film transistor, as shown in FIG. 1. The thin film transistor includes: a base substrate 10, and a gate electrode 11, a gate insulating layer 12, an active layer 13 and source-drain electrode layer 14, which are in turn located on the base substrate 10.

The thin film transistor further includes: an etch stop layer 15 located between the active layer 13 and the source-drain electrode layer 14, wherein orthogonal projection of the etch stop layer 15 on the base substrate 10 is of superposition with that of the active layer 13 on the base substrate 10; a portion of the etch stop layer 15 located directly under the source-drain electrode layer 14 is made of metal or metal alloy; and a portion of the etch stop layer 15 at a position corresponding to a region between a source electrode 141 and a drain electrode 142 of the source-drain electrode layer 14 is made of oxide of the metal or metal alloy, in which the oxide of the metal or metal alloy is an insulating material.

In the thin film transistor according to embodiments of the present invention, the etch stop layer is provided between the active layer and the source-drain electrode layer, and the portion of the etch stop layer that is in contact with the source and drain electrodes is made of metal or metal alloy so as to achieve electrical connection between the source and drain electrodes and the active layer without providing through hole and, meanwhile, the portion of the etch stop layer at a position corresponding to a region between the source electrode and the drain electrode may be oxidated by an oxidation process as the oxide of the metal or metal alloy so as to ensure insulation between the source electrode and the drain electrode when the thin film transistor is under a cutoff state, thereby ensuring the thin film transistor work properly. And because of the etch stop layer provided between the active layer and the source-drain electrode layer in the above thin film transistor, the etch barrier layer may not only prevent the active layer from being damaged when etching the source-drain electrode layer, but also prevent the active layer from other adverse effects from subsequent processes, such as adverse effects from water, hydrogen and oxygen, etc., thereby enhancing the performance of the thin film transistor.

In addition, during manufacturing the thin film transistor according to embodiments of the present invention, the etch stop layer and the active layer may be formed simultaneously through a single patterning process with adding an oxidation process and without adding additional patterning process, since the portion of the etch stop layer that is in contact with the source and drain electrodes is made of metal or metal alloy while the portion of the etch stop layer between the source electrode and the drain electrode is made of the oxide of the metal or metal alloy that is an insulating material, and the etch stop layer is the same as that of the active layer, thereby ensuring production efficiency.

Preferably, in an example of the thin film transistor according to the embodiments of the present invention, the etch barrier layer is made of any of molybdenum (Mo), titanium (Ti), tungsten (W), molybdenum alloy, and titanium alloy, or any of others metals or metal alloys that may be transformed into insulating material of oxide. However, the etch stop layer is not limited to these materials.

Further, in practice, in an example of the thin film transistor according to the embodiments of the present invention, the etch barrier layer may have a thickness in a range of 20 Å˜200 Å. However, the thickness of the etch stop layer is not limited here.

Preferably, in an example of the thin film transistor according to the embodiments of the present invention, the etch barrier layer may have a thickness in a range of 50 Å˜120 Å.

Further, in an example of the thin film transistor according to the embodiments of the present invention, the active layer may be made of metal oxide. However, the active layer is not limited to this.

Specifically, in an example of the thin film transistor according to the embodiments of the present invention, the metal oxide may be any of gallium-zinc oxide (GZO), amorphous indium-gallium-zinc oxide (α-IGZO), HIZO, indium-zinc oxide (IZO), amorphous indium-zinc oxide (α-IZO), zinc oxide:fluorine (ZnO:F), indium oxide:tin (In₂O₃:Sn), indium oxide:molybdenum (In₂O₃:M_{O}), Cd₂SnO₄, zinc oxide:aluminum (ZnO:Al), titanium oxide:niobium:(TiO₂:Nb) and Cd—Sn—O. However, the metal oxide is not limited to those.

Further, in practice, in an example of the thin film transistor according to the embodiments of the present invention, the thickness of the active layer may be configured in a range of 50 Å˜1000 Å. However, it is not herein limited to this.

Preferably, in an example of the thin film transistor according to the embodiments of the present invention, the source electrode and the drain electrode may be made of copper (Cu) with a small resistivity and the etch stop layer may be made of material different from that for the source and drain electrodes, thereby the resistance of the source and drain electrodes may be reduced.

Further, in practice, in an example of the thin film transistor according to the embodiments of the present invention, the thickness of the source-drain electrode layer may be configured in a range of 2000 Å˜8000 Å. However, it is not herein limited to this.

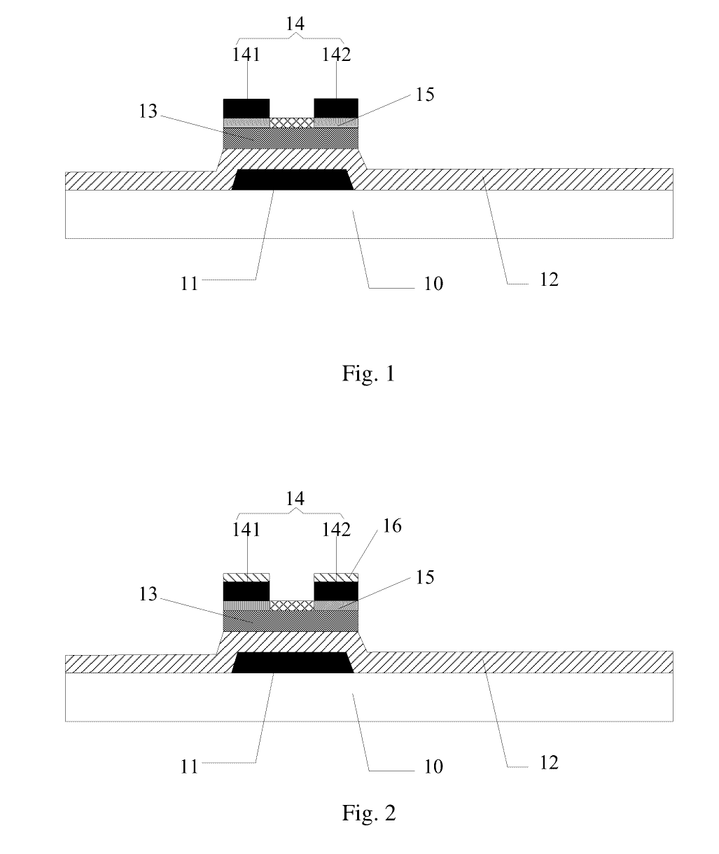

Further, in practice, since the copper electrode is exposed to oxygen ion and is thus easy to be oxidated, and even it might be peeled off when subject to serious oxidation, the thin film transistor according to embodiments of the present invention, as shown in FIG. 2, further includes an oxidation resistant layer 16 located on the source-drain electrode layer 14, orthogonal projection of the oxidation resistant layer 16 on the base substrate 10 is of superposition with that of the source-drain electrode layer 14 on the base substrate 10, thereby preventing the source-drain electrode layer 14 form oxidation.

Preferably, in an example of the thin film transistor according to the embodiments of the present invention, the oxidation resistant layer 16 is made of metal material, which is different from that for the source-drain electrode layer 14.

Specifically, in practice, in an example of the thin film transistor according to the embodiments of the present invention, the oxidation resistant layer 16 is made of any of molybdenum (Mo), titanium (Ti), tungsten (W), molybdenum alloy, and titanium alloy. However, it is not herein limited to this.

Further, in practice, in an example of the thin film transistor according to the embodiments of the present invention, the thickness of the oxidation resistant layer may be configured in a range of 20 Å˜800 Å. However, it is not herein limited to this.

Preferably, in practice, in an example of the thin film transistor according to the embodiments of the present invention, the gate electrode may be made of copper with a small resistivity, thereby reducing resistance of the gate electrode.

Specifically, in practice, in an example of the thin film transistor according to the embodiments of the present invention, the thickness of the gate electrode may be configured in a range of 2000 Å˜10000 Å. However, it is not herein limited to this.

Further, in an example of the thin film transistor according to the embodiments of the present invention, the gate insulating layer is made of nitride or oxynitride, etc. However, it is not herein limited to this.

Further, in an example of the thin film transistor according to the embodiments of the present invention, the thickness of the gate insulating layer may be configured in a range of 300 Å˜3000 Å. However, it is not herein limited to this.

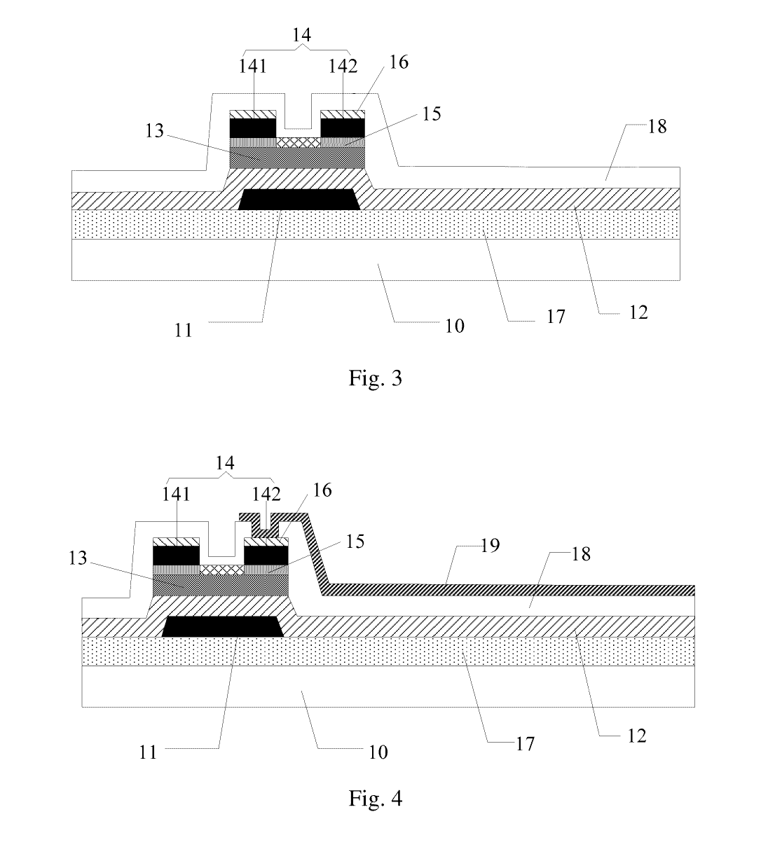

Further, in an example, the thin film transistor according to the embodiments of the present invention, as shown in FIG. 3, further includes a buffer layer 17 located between the gate electrode 11 and the base substrate 10, which increases an adhesion force between the gate electrode made of copper and the base substrate.

Further, in an example, the thin film transistor according to the embodiments of the present invention, as shown in FIG. 3, further includes a protective layer 18 covering the oxidation resistant layer 16, the etch stop layer 15 and the gate insulating layer 12, such that the thin film transistor obtains enhanced resistance ability of water vapor and air in external environment and thus obtains increased stability. The protective layer may be made of oxide, nitride or oxynitride, and is not particularly limited here. Preferably, the protective layer may be made of nitride of silicon.

In practice, in an example of the thin film transistor according to the embodiments of the present invention, the thickness of the protective layer may be configured in a range of 1000 Å˜3000 Å. However, it is not limited herein to this.

Based on the same invention concept, embodiments of the present invention further provide an array substrate, including the thin film transistor according to any one of the above embodiments of the present invention, which may be implanted with reference to the above embodiments of the thin film transistor. The repeated content is omitted here.

In practice, in an example, the array substrate according to the embodiments of the present invention, as shown in FIG. 4, further includes a transparent electrode 19 located on the protective layer 18. The transparent electrode is electrically connected to the drain electrode 142 in the source-drain electrode layer 14 via the through hole that penetrates through the protective layer 18.

Specifically, in an example of the array substrate according to the embodiments of the present invention, the transparent electrode 19 may be made of Indium-tin oxide (no) or indium-zinc oxide (IZO), or other transparent metal oxide. However, it is not limited herein to this. Further, in an example, the thickness of the transparent electrode may be configured in a range of 300 Å˜1500 Å. However, it is not limited herein to this.

Further, in an example, the array substrate according to the embodiments of the present invention further includes a data signal line configured in the same layer as the source-drain electrode layer and a gate scan line configured in the same layer as the gate electrode. However, it is not limited herein to this.

Preferably, in an example of the array substrate according to the embodiments of the present invention, an oxidation resistant layer is provided on the data signal line and located in the same layer as the oxidation resistant layer on the source-drain electrode layer, thereby preventing the copper electrode from oxidation.

Specifically, the array substrate according to embodiments of the present invention may be applied in a liquid crystal display (LCD) display panel, or may be applied in an organic light emitting diode (OLED) display panel. However, it is not limited herein to this.

Based on the same invention concept, embodiments of the present invention further provide a display device, including the array substrate according to any one of the above embodiments of the present invention. The display device may comprise a liquid crystal display (LCD) display panel, or an organic light emitting diode (OLED) display panel. It is known or common means for those skilled in the art to implement the others indispensable components in the display panel, which is not repeated herein and is not intended to be considered as limitation of the present invention. Implementing of the display panel may be referring to the above embodiments of the array substrate. The repeated content thereof is omitted.

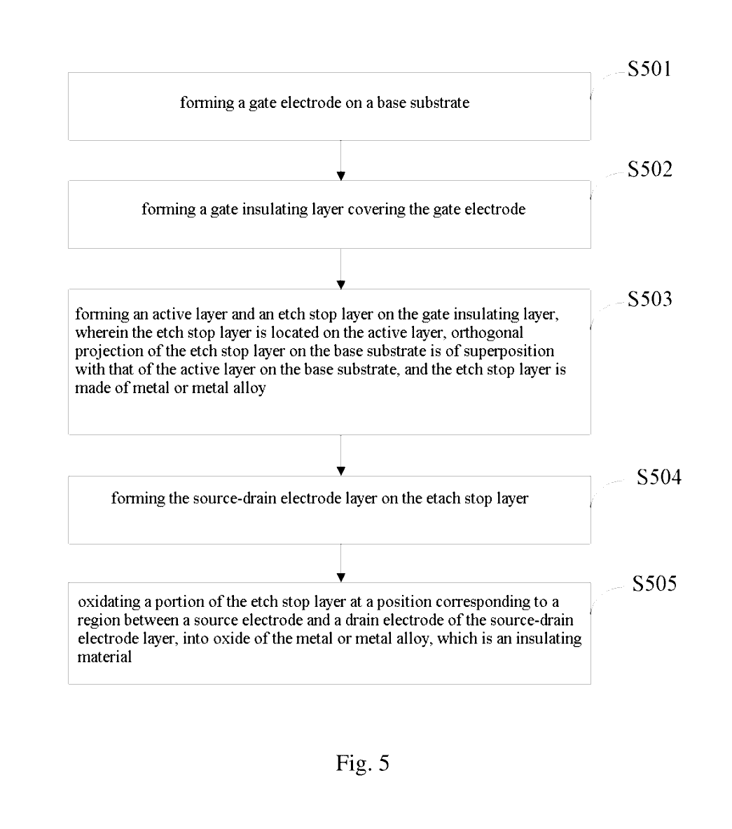

Based on the same invention concept, embodiments of the present invention further provide a method of manufacturing a thin film transistor, as shown in FIG. 5. The method includes following steps:

S501: forming a gate electrode on a base substrate;

S502: forming a gate insulating layer covering the gate electrode;

S503: forming an active layer and an etch stop layer on the gate insulating layer, wherein the etch stop layer is located on the active layer, orthogonal projection of the etch stop layer on the base substrate is of superposition with that of the active layer on the base substrate, and the etch stop layer is made of metal or metal alloy;

S504: forming the source-drain electrode layer on the etch stop layer;

S505: oxidating a portion of the etch stop layer at a position corresponding to a region between a source electrode and a drain electrode of the source-drain electrode layer, into oxide of the metal or metal alloy, which is an insulating material.

The method of manufacturing the thin film transistor according to embodiments of the present invention is designed to form the active layer and the etch stop layer on the gate insulating layer before forming the source-drain electrode layer, such that the orthogonal projection of the etch stop layer on the base substrate is of superposition with that of the active layer on the base substrate, and the etch stop layer is made of the metal or metal alloy. In this instance, the etch stop layer may not only prevent the active layer from being damaged when etching the source-drain electrode layer, but also prevent the active layer from other adverse effects from subsequent processes, such as adverse effects from water, hydrogen and oxygen, etc., thereby enhancing the performance of the thin film transistor.

Preferably, according to the method of manufacturing the thin film transistor, the step of forming an active layer and an etch stop layer on the gate insulating layer includes:

forming an active layer film on the gate insulating layer;

forming an etch stop layer film on the active layer; and

patterning the active layer film and the etch stop layer film by a single patterning process, to form the active layer and the etch stop layer on the gate insulating layer. By this way, the etch stop layer may be obtained while forming the active layer through a single patterning process, and thus it is not needed to separately add any patterning process, while only adding an oxidation process, thereby reducing product cost and increasing work efficiency.

Specifically, according to the method of manufacturing the thin film transistor, the etch stop layer may be made of the metal or metal alloy, which is different from that for the source-drain electrode layer. In this instance, since the etchant for etching copper has a more rapid speed of etching the source-drain electrode layer with respective to etching the etch stop layer due to a rather large etching selection ratio between the etch stop layer and the source-drain electrode layer, the portion of the source-drain electrode layer film between the source electrode and the drain electrode may be removed through a single etching process while the etch stop layer may be left under the source electrode and the drain electrode.

Specifically, according to the method of manufacturing the thin film transistor, the etch stop layer may be made of any of molybdenum (Mo), titanium (Ti), tungsten (W), molybdenum alloy, and other metals or metal alloys that may be transformed into insulating oxide. However, it is not limited herein to this.

Further, according to the method of manufacturing the thin film transistor, the etch stop layer may be deposited by sputtering or thermally evaporating process. It is understood that the etch stop layer may be deposited by other known methods. Specifically, the thickness of the etch stop layer may be configured in a range of 20 Å˜200 Å. However, it is not limited herein to this.

Preferably, according to the method of manufacturing the thin film transistor, the etch barrier layer may have a thickness in a range of 50 Å˜120 Å.

Preferably, according to the method of manufacturing the thin film transistor, the source-drain electrode layer may be made of copper, thereby reducing resistance; and

the etch stop layer may be made of a material that is different from that for the source-drain electrode layer.

Preferably, in order to prevent source-drain electrode layer from oxidation, after forming the source-drain electrode layer on the etch stop layer, the method of manufacturing the thin film transistor according to embodiments of the present invention further includes:

forming an oxidation resistant layer on the source-drain electrode layer, orthogonal projection of the oxidation resistant layer on the base substrate being of superposition with that of the source-drain electrode layer on the base substrate;

wherein, the oxidation resistant layer is made of metal that is different from that for the source-drain electrode layer.

Preferably, in order to reduce the number of patterning processes, according to the method of manufacturing the thin film transistor, the steps of forming the source-drain electrode layer and forming the oxidation resistant layer include:

forming a source-drain electrode film on the etch stop layer;

forming an oxidation resistant layer film on the source-drain electrode film; and

patterning the source-drain electrode film and the oxidation resistant layer film through a single patterning process to form the source-drain electrode and the oxidation resistant layer. By this way, the oxidation resistant layer may be obtained while forming the patterning of the source-drain electrode through a single patterning process without adding any other patterning process, thereby reducing product cost and ensuring work efficiency.

Specifically, according to the method of manufacturing the thin film transistor, the source-drain electrode film with a thickness in a range of 2000 Å˜8000 Å and the oxidation resistant layer film with a thickness in a range of 20 Å˜800 Å may be deposited by sputtering or thermally evaporating process. The oxidation resistant layer may be made of molybdenum (Mo), titanium (Ti), tungsten (W), molybdenum alloy, or titanium alloy, etc. However, it is not limited herein to this.

Specifically, according to the method of manufacturing the thin film transistor, preferably, the gate electrode is made of copper. In practice, a copper film with a thickness in a range of 2000 Å˜10000 Å may be deposited on the base substrate by sputtering or thermally evaporating process. Then, the copper film may be patterned to obtain the gate electrode.

Further, in practice, in order to add an adhesion force between the gate electrode made of copper material and the base substrate, before forming the gate electrode, the method according to the embodiments of the present invention further includes:

forming a buffer layer on the base substrate.

Further, in practice, according to the method of manufacturing the thin film transistor, the gate insulating layer with a thickness in a range of 300 Å˜3000 Å may be deposited by plasma enhanced chemical vapor (PECVD) process. Specifically, the gate insulating layer may be made of nitride or oxynitride and the corresponding reaction gases for the process may include SiH₄, NH₃ and N₂, or include SiH₂Cl₂, NH₃ and N₂, or include SiH₄, NH₃, N₂O and N₂. however, it is not limited herein to this.

Further, according to the method of manufacturing the thin film transistor, the active layer may be made of metal oxide, however, it is not limited herein to this. Specifically, the metal oxide may be any of gallium-zinc oxide (GZO), amorphous indium-gallium-zinc oxide (α-IGZO), HIZO, indium-zinc oxide (IZO), amorphous indium-zinc oxide (α-IZO), zinc oxide:fluorine (ZnO:F), indium oxide:tin (In₂O₃:Sn), indium oxide:molybdenum (In₂O₃:M_{O}), Cd₂SnO₄, zinc oxide:aluminum (ZnO:Al), titanium oxide:niobium:(TiO₂:Nb) and Cd—Sn—O. However, the metal oxide is not limited to this.

In practice, according to the method of manufacturing the thin film transistor, the active layer with a thickness in a range of 50 Å˜1000 Å may be deposited by sputtering process.

Further, in order to enhancing resistance ability of the thin film transistor to water vapor and air in external environment, after oxidating the portion of the etch stop layer at a position corresponding the region between the source electrode and the drain electrode in the source-drain electrode layer, the method according to the embodiments of the present invention further includes:

forming a protective layer 18 covering the oxidation resistant layer 16, the etch stop layer 15 and the gate insulating layer. Specifically, the protective layer 18 may be made of oxide, nitride or oxynitride; however, it is not limited herein to this.

Specifically, according to the method of manufacturing the thin film transistor, the protective layer 18 may be deposited by PECVD and may have a thickness in a range of 1000 Å˜3000 Å. Specifically, the protective layer 18 may be made of oxide of silicon and the corresponding reaction gases for forming it may comprise SiH₄ and N₂O. When the protective layer 18 is made of nitride or oxynitride, the corresponding reaction gases for forming it may include SiH₄, NH₃ and N₂, or include SiH₂Cl₂, NH₃ and N₂; however, it is not limited herein to this.

Further, when the thin film transistor provided according to the embodiments of the present invention is applied in a display device, after forming the protective layer, the method may further include:

patterning the protective layer to form a through hole penetrating through the protective layer; and

forming a transparent electrode on the protective layer, the transparent electrode being connected to the oxidation resistant layer on the drain electrode via the through hole in the protective layer and thereby being electrically connected to the drain electrode.

Specifically, the transparent electrode may be made of indium-tin oxide (ITO) or indium-zinc oxide (IZO), or other transparent metal oxide; however, it is not limited to this. Further, in practice, the transparent electrode may be deposited by sputtering or thermally evaporating process and may have a thickness in a range of 300 Å˜1500 Å. However, it is not limited to this.

The above method according to the embodiments of the present invention will be described in detail by referring to the array substrate as shown in FIG. 4 as an example. The method may specifically include the steps of:

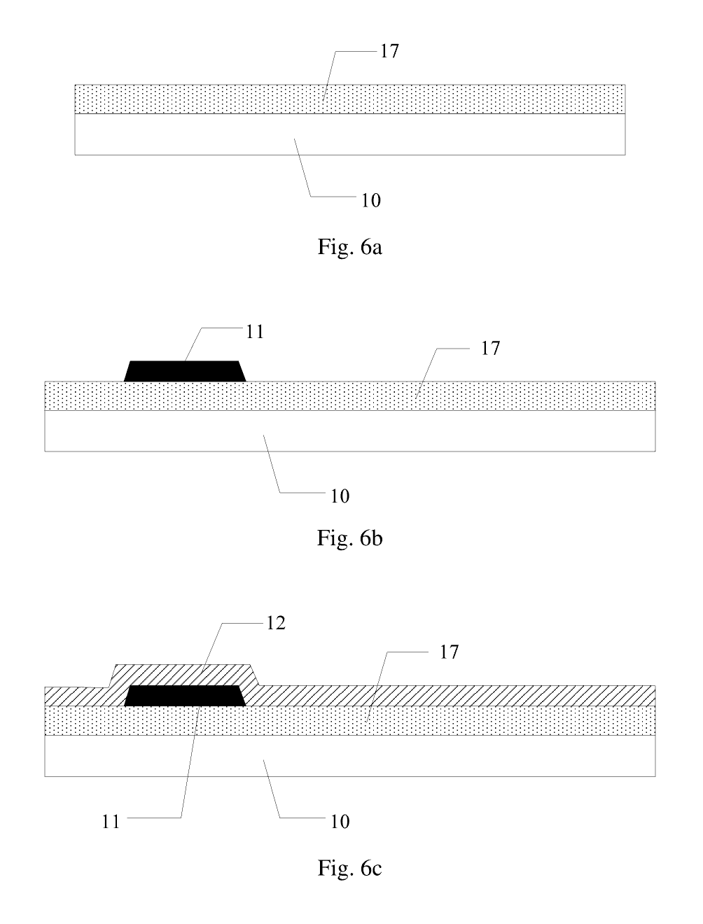

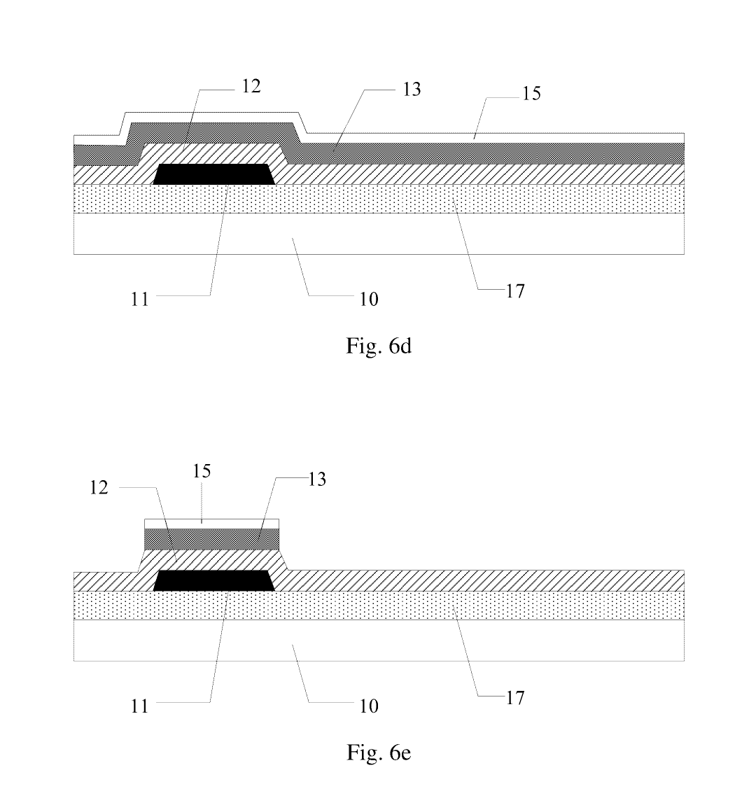

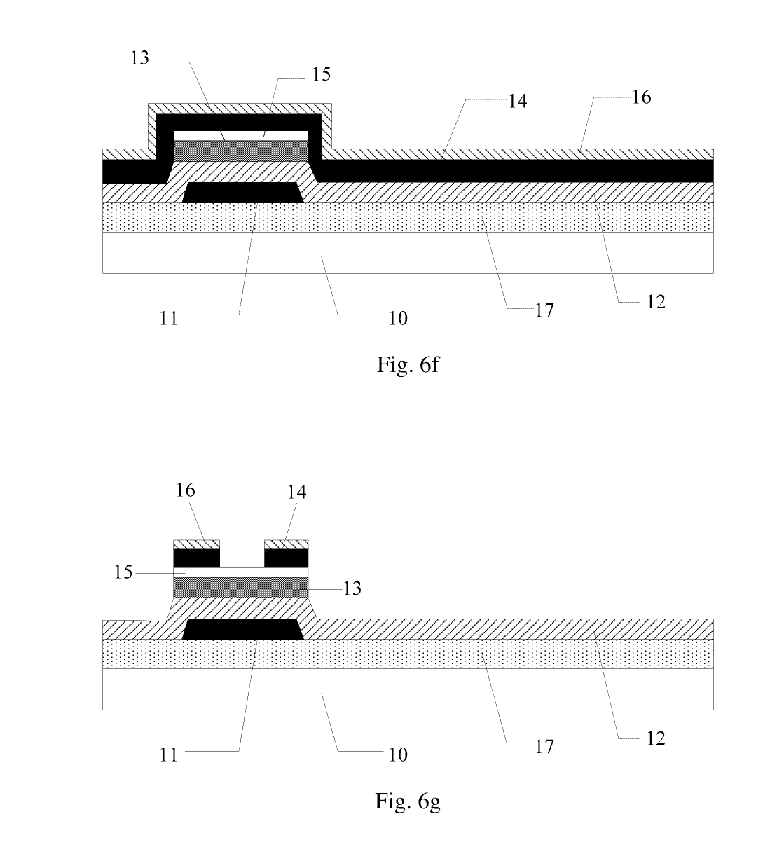

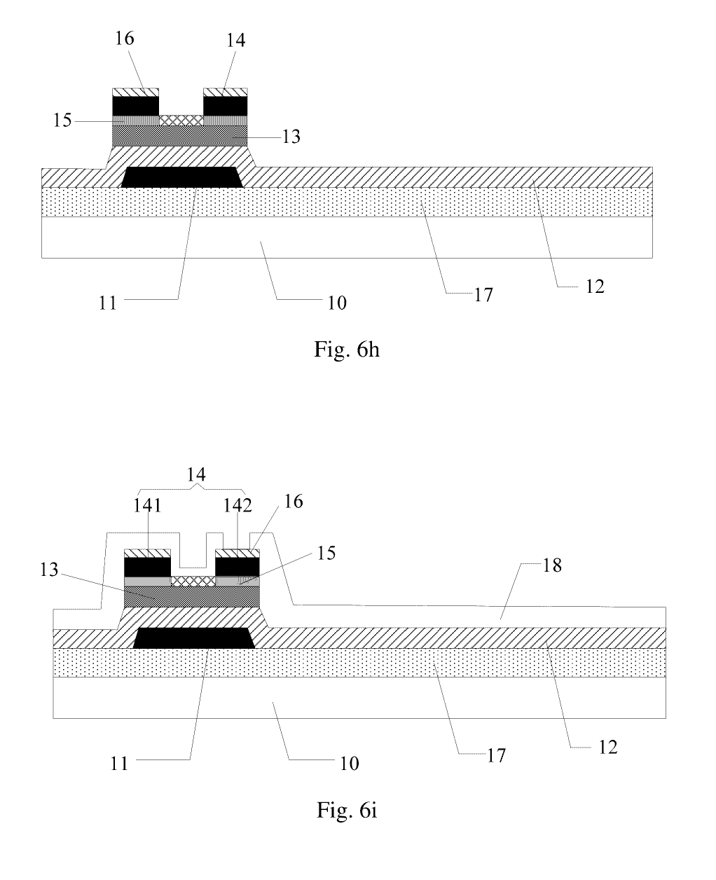

(1) depositing a buffer layer 17 on the base substrate 10, as shown in FIG. 6a;
(2) forming a gate electrode 11 on the buffer layer 17, as shown in FIG. 6b;

Specifically, in practice, the gate electrode may be made of copper and may have a thickness in a range of 2000 Å˜10000 Å. However, it is not limited herein to this;

(3) forming a gate insulating layer 12 covering the gate electrode, as shown in FIG. 6c;

Specifically, in practice, the gate insulating layer may be made of nitride or oxynitride and may have a thickness in a range of 300 Å˜3000 Å. However, it is not limited herein to this;

(4) forming an active layer film and an etch stop layer film on the gate insulating layer, as shown in FIG. 6d;

Specifically, in practice, the active layer may be made of metal oxide and may have a thickness in a range of 50 Å˜1000 Å. However, it is not limited herein to this;

Specifically, in practice, the etch stop layer may be made of molybdenum (Mo), titanium (Ti), tungsten (W), molybdenum alloy, or titanium alloy, etc. and may have a thickness in a range of 20 Å˜1000 Å. However, it is not limited herein to this;

(5) patterning the active layer film and the etch stop layer film such that the active layer 13 and the etch stop layer may be formed through single patterning process, as shown in FIG. 6e;
(6) forming a source-drain electrode layer film and an oxidation resistant layer film in turn to cover the etch stop layer 15, as shown in FIG. 6f;

Specifically, in practice, the source-drain electrode layer may be made of copper and may have a thickness in a range of 2000 Å˜8000 Å. However, it is not limited herein to this;

Specifically, in practice, the oxidation resistant layer may be made of molybdenum (Mo), titanium (Ti), tungsten (W), molybdenum alloy, or titanium alloy, etc. and may have a thickness in a range of 20 Å˜800 Å. However, it is not limited herein to this;

(7) patterning the source-drain electrode layer film and the oxidation resistant layer film such that the source-drain electrode layer 14 and the oxidation resistant layer 16 may be formed through single patterning process, as shown in FIG. 6g;
(8) performing an oxidation process to a portion of the etch stop layer 15 at a position corresponding to a region between the source electrode 141 in the source-drain electrode layer 14 and the drain electrode 142 in the source-drain electrode layer 14 such that the portion of the etch stop layer 15 may be transformed into insulating material, as shown in FIG. 6h;
(9) forming the protective layer 18 on the oxidation resistant layer 16, as shown in FIG. 6i;

Specifically, in practice, the protective layer may be made of oxide, nitride or oxynitride, and however, it is not limited to this. Preferably, the protective layer may be made of silicon nitride and have a thickness in a range of 1000 Å˜3000 Å. However, it is not limited herein to this.

(10) forming a transparent electrode 19 on the protective layer 18, such that the transparent electrode 19 is connected to the oxidation resistant layer on the drain electrode 142 via the through hole penetrating through the protective layer, so as to achieve electrical connection between the transparent electrode 19 and the drain electrode 142, as shown in FIG. 4.

Specifically, in practice, the transparent electrode may be made of indium-tin oxide (ITO) or indium-zinc oxide (IZO) and may have a thickness in a range of 300 Å˜1500 Å. However, it is not limited herein to this.

In sum, in the array substrate formed through the above steps (1)˜(10), the etch stop layer may be formed between the active layer and the source-drain electrode layer and the oxidation resistant layer may be formed on the source-drain electrode layer without adding any patterning process, thereby the etch stop layer may not only prevent the active layer from being damaged when etching the source-drain electrode layer, but also prevent the active layer from other adverse effects from subsequent processes, such as adverse effects from water, hydrogen and oxygen, etc. Further, the oxidation resistant layer may prevent the source-drain electrode layer from oxidation. Thus, the thin film transistor manufactured by the above method may have a good performance and may meet requirements of large-size display device.

The thin film transistor, the method of manufacturing the same, the array substrate and the display device according to the embodiments of the present invention may ensure electrical connection between the source and drain electrodes and the active layer without configuring any through hole due to providing the etch stop layer between the active layer and the source-drain electrode layer and forming the portion of the etch stop layer that is in contact with the source and drain electrodes by metal or metal alloy; and may ensure insulation between the source electrode and the drain electrode when the thin film transistor is turned-off, ensuring normal operation of the thin film transistor, by oxidating the portion of the etch stop layer at the position between the source electrode and the drain electrode as insulating material through the oxidation process. The etch stop layer may not only prevent the active layer from being damaged when etching the source-drain electrode, but also prevent the active layer from other adverse effects from subsequent processes, such as adverse effects from water, hydrogen and oxygen, etc., thereby enhancing performance of the thin film transistor, just because of providing the etch stop layer between the active layer and the source-drain electrode layer in the thin film transistor.

Obviously, it is obvious to modify and change the embodiments of the present invention without departing from inspirit and scope of the present invention. These modification and change to the embodiments of the present invention shall be covered in the scope of the present invention if they fall within the scope of the claims and equivalents.

1. A thin film transistor, comprising: a base substrate, and a gate electrode, a gate insulating layer, an active layer and a source-drain electrode layer, which are in turn located on the base substrate,
wherein the thin film transistor further comprises:
an etch stop layer located between the active layer and the source-drain electrode layer, orthogonal projection of the etch stop layer on the base substrate being of superposition with that of the active layer on the base substrate, a portion of the etch stop layer under the source-drain electrode layer being made of metal or metal alloy, and a portion of the etch stop layer at a position corresponding to a region between a source electrode and a drain electrode in the source-drain electrode layer being made of oxide of the metal or metal alloy.

2. The thin film transistor according to claim 1, wherein the source-drain electrode layer is made of copper and the etch stop layer is made of a material that is different from that of the source-drain electrode layer.

3. The thin film transistor according to claim 1, further comprising:
an oxidation resistant layer located on the source-drain electrode layer, wherein orthogonal projection of the oxidation resistant layer on the base substrate is of superposition with that of the source-drain electrode layer on the base substrate.

4. The thin film transistor according to claim 3, wherein the oxidation resistant layer is made of a metal material, which is different from the material of the source-drain electrode layer.

5. The thin film transistor according to claim 1, wherein the etch stop layer is made of any of molybdenum, titanium, tungsten, molybdenum alloy, and titanium alloy.

6. The thin film transistor according to claim 2, wherein the etch stop layer is made of any of molybdenum, titanium, tungsten, molybdenum alloy, and titanium alloy.

7. The thin film transistor according to claim 1, wherein the etch stop layer has a thickness in a range of 20 Å˜200 Å.

8. The thin film transistor according to claim 2, wherein the etch stop layer has a thickness in a range of 20 Å˜200 Å.

9. The thin film transistor according to claim 3, wherein the oxidation resistant layer is made of any of molybdenum, titanium, tungsten, molybdenum alloy, and titanium alloy.

10. The thin film transistor according to claim 1, wherein the active layer is made of metal oxide.

11. The thin film transistor according to claim 3, further comprising a protective layer configured to cover the oxidation resistant layer, the etch stop layer and the gate insulating layer.

12. A method of manufacturing a thin film transistor, wherein the method comprises steps of:
forming a gate electrode on a base substrate;
forming a gate insulating layer covering the gate electrode;
forming an active layer and an etch stop layer on the gate insulating layer, wherein the etch stop layer is located on the active layer such that orthogonal projection of the etch stop layer on the base substrate is of superposition with that of the active layer on the base substrate, the etch stop layer being made of metal or metal alloy;
forming a source-drain electrode layer on the etch stop layer;
oxidating a portion of the etch stop layer at a position corresponding to a region between a source electrode of the source-drain electrode layer and a drain electrode of the source-drain electrode layer, which is made of metal or metal alloy, to form an oxide of the metal or metal alloy.

13. The method according to claim 12, wherein the step of forming the active layer and the etch stop layer on the gate insulating layer includes:
forming an active layer film on the gate insulating layer;
forming an etch stop layer film on the active layer; and
patterning the active layer film and the etch stop layer film by a single patterning process, so as to form the active layer and the etch stop layer on the gate insulating layer.

14. The method according to claim 12, wherein the source-drain electrode layer is made of copper; and
the etch stop layer is made of a material that is different from the material of the source-drain electrode layer.

15. The method according to claim 12, wherein, after forming the source-drain electrode layer on the etch stop layer, the method further includes:
forming an oxidation resistant layer on the source-drain electrode layer, such that orthogonal projection of the oxidation resistant layer on the base substrate is of superposition with that of the source-drain electrode layer on the base substrate.

16. The method according to claim 15, wherein the step of forming the source-drain electrode layer and the oxidation resistant layer includes:
forming a source-drain electrode layer film on the etch stop layer;
forming a oxidation resistant layer film on the source-drain electrode layer film; and
patterning the source-drain electrode layer film and the oxidation resistant layer film through a single patterning process to form the source-drain electrode layer and the oxidation resistant layer.

17. An array substrate comprising the thin film transistor according to claim 1.

18. The array substrate according to claim 17, further comprising a transparent electrode on the protective layer, the transparent electrode being electrically connected to the drain electrode of the source-drain electrode layer via a through hole that penetrates through the protective layer.

19. The array substrate according to claim 18, wherein the transparent electrode is made of Indium-tin oxide (ITO) or indium-zinc oxide (IZO), or other transparent metal oxide, with a thickness in a range of 300 Å˜1500 Å.

20. A display device comprising the array substrate according to claim 17.
